(19) United States
(12) Patent Application Publication
(10) Pub. No.: US 2007/0108611 A1
(43) Pub. Date: May 17, 2007

(54) Stacking method and stacked structure for attaching memory components to associated device

(75) Inventors: Gerald Keith Bartley, Rochester, MN (US); Darryl John Becker, Rochester, MN (US); Paul Eric Dahlen, Rochester, MN (US); Philip Raymond Germann, Oronoco, MN (US); Andrew Benson Maki, Rochester, MN (US); Mark Owen Maxson, Mantorville, MN (US)

Correspondence Address: IBM CORPORATION;ROCHESTER IP LAW DEPT 917, 3605 HIGHWAY 52 N, ROCHESTER, MN, 55901-7829, US

(73) Assignee: International Business Machines Corporation, Armonk, NY (US)

(21) Appl. No.: 11/282,082

(22) Filed: Nov. 17, 2005

(51) Int. Cl. H01L 23/48

(52) U.S. Cl. 257/738

(57) ABSTRACT

A stacking method and structure for attaching memory components to a ball grid array (BGA) device are provided. A specialized carrier includes multiple memory devices such as memory die, or chip scale packaging (CSP) memory. The specialized carrier is attached to a mating supporting carrier to form a stacked structure. The mating supporting carrier includes an associated ball grid array (BGA) device for the multiple devices of the specialized carrier.

### FIELD OF THE INVENTION

The present invention relates generally to the electronic packaging field, and more particularly, relates to a stacking method for attaching memory components to an associated device, such as a ball grid array (BGA) type device.

### RELATED APPLICATION

A related application entitled SOCKET ASSEMBLY WITH INCORPORATED MEMORY STRUCTURE by Gerald K. Bartley, Darryl J. Becker, Paul E. Dahlen, Philip R Germann, Andrew B. Maki, Mark O. Maxson, Ser. No. ______, is being filed on the same date herewith.

### DESCRIPTION OF THE RELATED ART

As used in the following description and claims the terms ball grid array (BGA) device and BGA connections are not limited to BGA solder connections and should be understood to include multiple various other chip carrier technologies including, for example, Land Grid Array (LGA), pin grid array, and copper-copper thermal compression connections and devices.

A limitation for many processor type products is that of memory density and bandwidth to that memory. Traditional solutions to this challenge involve using, among other techniques, multiple layers of memory hierarchy (including on-die memory caches), large off module bus structures (which drives cost, noise, card level complexity, and larger chips), or conventional multi-chip packages, and the like.

Approaches that involve multi-chip packages usually have yield limitations and test concerns, known-good-die cost adders, and the like. Traditional approaches suffer from cost, card-to-module complexity, performance limitations, and the like.

A need exists for an improved packaging arrangement for memory and similar components with an associated device.

### SUMMARY OF THE INVENTION

A principal aspect of the present invention is to provide a stacking method for attaching memory components to a ball grid array (BGA) device. Other important aspects of the present invention are to provide such stacking method for attaching memory components to a ball grid array (BGA) device substantially without negative effect and that overcome many of the disadvantages of prior art arrangements.

In brief, a stacking method and structure for attaching memory components to a ball grid array (BGA) device are provided. A specialized carrier includes multiple memory devices such as memory die, or chip scale packaging (CSP) memory. The specialized carrier is attached to a mating supporting carrier to form a stacked structure. The mating supporting carrier includes an associated ball grid array (BGA) device for the multiple devices of the specialized carrier.

In accordance with features of the invention, the specialized carrier includes a generally centrally disposed opening generally aligned with and surrounding the associated ball grid array (BGA) device of the mating supporting carrier in the stacked structure. The multiple memory devices are disposed around the centrally disposed opening on the specialized carrier.

In accordance with features of the invention, the multiple memory devices are disposed on one or both upper and lower surfaces of the specialized carrier. The multiple memory devices are supported and electrically connected by the specialized carrier.

### BRIEF DESCRIPTION OF THE DRAWINGS

The present invention together with the above and other objects and advantages may best be understood from the following detailed description of the preferred embodiments of the invention illustrated in the drawings, wherein:

FIG. 1 is an exploded perspective view not to scale illustrating a stacked structure for attaching memory or similar components to a ball grid array (BGA) type device in accordance with the preferred embodiment; and

FIG. 2 is a cross-sectional side view not to scale of the stacked structure for attaching memory or similar components to a ball grid array (BGA) type device of FIG. 1 in accordance with the preferred embodiment.

### DETAILED DESCRIPTION OF THE PREFERRED EMBODIMENTS

In accordance with features of the preferred embodiments, a specialized carrier is provided for use with standard chip carrier technologies to allow the incorporation of multiple devices such as memory die, or chip scale packaging (CSP) memory. CSP memory packaging uses electrical connections to a printed circuit board (PCB) through a ball grid array (BGA) on the mating or underside of the package, rather than pins to connect the chip to the printed circuit board (PCB). Attaching the specialized carrier to the standard chip carrier could be solder, for example using a BGA technology, or copper-copper thermal compression, or potentially land grid array (LGA) technology.

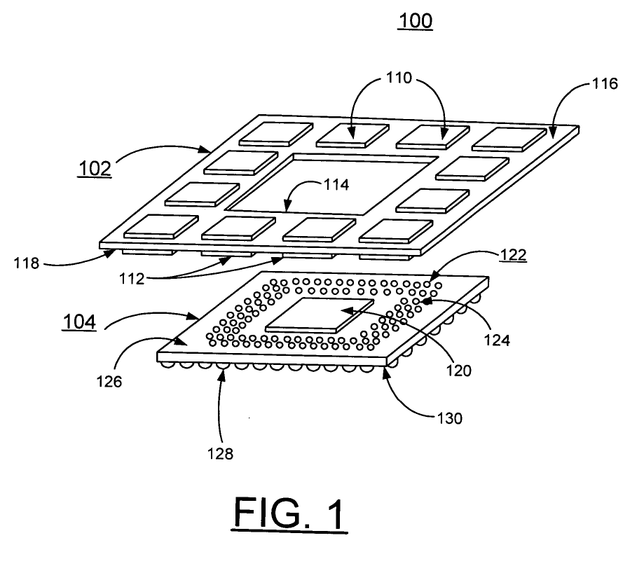

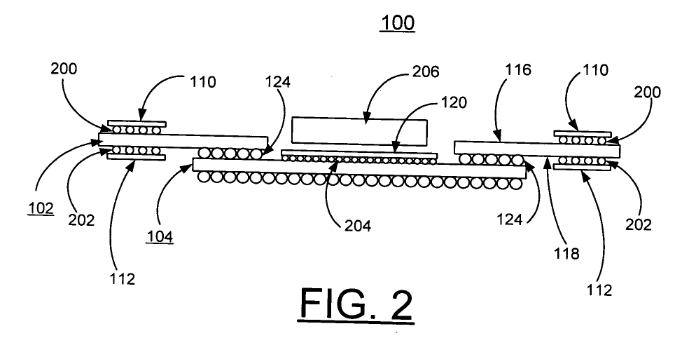

Having reference now to the drawings, in FIGS. 1 and 2, there is shown a stacked structure generally designated by the reference character 100 for attaching memory or similar components to a ball grid array (BGA) type device in accordance with the preferred embodiment. Stacked structure 100 includes a specialized carrier generally designated by the reference character 102 for stacked engagement with a mating chip carrier generally designated by the reference character 104.

As shown, specialized carrier 102 includes a plurality of devices 110 and 112, such as memory die, or chip scale packaging (CSP) memory, respectively supported on opposite surfaces of the carrier. Specialized carrier 102 includes a generally centrally located opening or cut out 114. Multiple devices 110, 112 respectively are mounted proximate to the cut out 114 on a top surface 116 and a bottom surface 118 of the specialized carrier 102.

It should be understood that the present invention is not limited to the illustrated configuration of the devices 110, 112; various other configurations could be provided, for example, where the memory devices 110, 112 are arranged in a non-symmetrical fashion around a less central opening in the specialized carrier 102.

Mating chip carrier 104 includes a generally centrally located die 120, such as a processor die. The cut out 114 in the specialized carrier 102 is provided to accommodate the centrally located die 120 of the mating chip carrier 104, under-fill, heatsink, over-mold compounds and the like.

Mating chip carrier 104 includes a predefined pattern generally designated by the reference character 122 of electrical connections 124 on an upper surface 126 arranged as, for example, a ball grid array (BGA) for electrically connecting to the specialized carrier 102. Mating chip carrier 104 includes a plurality of electrical connections 128 on a lower surface 130 also arranged as, for example, a ball grid array (BGA).

Referring also to FIG. 2, as illustrated the single or double-sided memory devices 110, 112 are electrically connected to the specialized carrier 102, for example, with a respective ball grid array (BGA) or other similar electrical connections such as die bumps or wirebond 200, 202. Each of the specialized carrier 102 and the mating chip carrier 104 is formed by, for example, a substrate, or a printed circuit board (PCB).

The specialized carrier 102 and the mating chip carrier 104 optionally have internal horizontal wiring layers and vertical connections that are omitted from the drawings for simplicity. The stacked structure 100 enables a short signal path between the memory devices 110,112 and the centrally located associated die 120, for example processor device, which is supported by the mating chip carrier 104. The centrally located die 120 is electrically connected to the mating chip carrier 104, for example, with a respective ball grid array (BGA) 204.

The stacked structure 100 optionally further includes a spreader or lid 206 coupled to the centrally located die 120. Mating chip carrier 104 is mounted to a printed circuit board or the like (not shown) with electrical connections 128 on the lower surface 130.

It should be understood that the present invention is not limited to illustrated arrangement of stacked structure 100. Various shapes and other arrangements of stacked structure 100 can be provided in accordance with the present invention. For example, the centrally located die 120 could be more than one device or chip.

In accordance with advantages of the preferred embodiments, the separate carriers 102,104 advantageously are tested and qualified for production independently. The separate carriers 102, 104 advantageously isolate the final assembly and/or stacked structure 100 from problems typically resulting from memory die revisions and technology migrations.

In accordance with advantages of the preferred embodiments, the stacked structure 100 eliminates the need for off module or through the PCB memory input/output (I/O), and the electrical issues, which typically result. The stacked structure 100 reduces the required complexity of the specialized carrier 102 and mating chip carrier 104, keeping memory signals within the assembly of the stacked structure 100.

In accordance with advantages of the preferred embodiments, it should be understood that the stacked structure 100 enables the potential to provide multiple memory carrier implementations for the stacked structure 100, for example, each with different speeds, capacities, or silicon technologies with a substantially identical or similar specialized carrier 102.

While the present invention has been described with reference to the details of the embodiments of the invention shown in the drawing, these details are not intended to limit the scope of the invention as claimed in the appended claims.

What is claimed is:

1. A stacked structure for attaching memory components to an associated ball grid array (BGA) device comprising:
a specialized carrier including multiple memory devices;
a mating supporting carrier being attached to said specialized carrier to form the stacked structure; and
said mating supporting carrier including an associated ball grid array (BGA) device for the multiple devices of the specialized carrier.

2. A stacked structure as recited in claim 1 wherein said multiple memory devices include memory die.

3. A stacked structure as recited in claim 1 wherein said multiple memory devices include chip scale packaging (CSP) memory.

4. A stacked structure as recited in claim 1 wherein said specialized carrier includes a generally centrally disposed opening generally aligned with and surrounding said associated ball grid array (BGA) device of the mating supporting carrier in the stacked structure.

5. A stacked structure as recited in claim 1 wherein said multiple memory devices are disposed proximate to said centrally disposed opening in said specialized carrier.

6. A stacked structure as recited in claim 1 wherein said multiple memory devices are disposed on at least one of an upper surface and a lower surface of the specialized carrier.

7. A stacked structure as recited in claim 1 wherein said multiple memory devices are supported and electrically connected by said specialized carrier.

8. A stacked structure as recited in claim 1 wherein said specialized carrier includes a printed circuit board (PCB).

9. A stacked structure as recited in claim 1 wherein said specialized carrier includes a substrate.

10. A method for attaching memory components to an associated ball grid array (BGA) device comprising:
providing a specialized carrier including multiple memory devices;
providing a mating supporting carrier including the associated ball grid array (BGA) device for the multiple devices of the specialized carrier; and
attaching said mating supporting carrier to said specialized carrier to form a stacked structure.

11. A method for attaching memory components as recited in claim 10 wherein said multiple memory devices include memory die.

12. A method for attaching memory components as recited in claim 10 wherein said multiple memory devices include chip scale packaging (CSP) memory.

13. A method for attaching memory components as recited in claim 10 wherein providing said specialized carrier includes providing a generally centrally disposed opening generally aligned with and surrounding said associated ball grid array (BGA) device of the mating supporting carrier in the stacked structure.

14. A method for attaching memory components as recited in claim 13 wherein providing said specialized carrier includes providing said multiple memory devices proximate to said centrally disposed opening on said specialized carrier.
